(19) United States
(12) Patent Application Publication
(10) Pub. No.: US 2024/0266274 A1
(43) Pub. Date: Aug. 8, 2024

(54) SEMICONDUCTOR DEVICE

(71) Applicant: SUMITOMO ELECTRIC INDUSTRIES, LTD., Osaka (JP)

(72) Inventor: Noriyoshi SUDA, Osaka-shi (JP)

(73) Assignee: SUMITOMO ELECTRIC INDUSTRIES, LTD., Osaka (JP)

(21) Appl. No.: 18/425,166

(22) Filed: Jan. 29, 2024

(30) Foreign Application Priority Data
Feb. 2, 2023 (JP) 2023-014719

(51) Int. Cl. H01L 23/498; H01L 23/00; H01L 23/31

(52) U.S. Cl. CPC H01L 23/49838; H01L 23/3107; H01L 24/48; H01L 2224/48155; H01L 2924/181; H01L 2924/19105

(57) ABSTRACT

A semiconductor device includes a semiconductor chip, a lead frame, and a bonding wire. The lead frame includes a base portion on which the semiconductor chip is mounted, a first lead separated from the base portion and electrically connected to the semiconductor chip, and a second lead separated from the base portion, and the bonding wire electrically connects the base portion to the second lead.

### CROSS REFERENCE TO RELATED APPLICATIONS

This application claims priority based on Japanese Patent Application No. 2023-014719 filed on Feb. 2, 2023, and the entire contents of the Japanese patent applications are incorporated herein by reference.

### FIELD

The present disclosure relates to a semiconductor device.

### BACKGROUND

There is known a semiconductor device in which a semiconductor chip is mounted on a lead frame (for example, Patent Document 1: Japanese Laid-open Patent Publication No. 10-050891).

### SUMMARY

A semiconductor device according to the present disclosure includes a semiconductor chip, a lead frame, and a bonding wire. The lead frame includes a base portion on which the semiconductor chip is mounted, a first lead separated from the base portion and electrically connected to the semiconductor chip, and a second lead separated from the base portion, and the bonding wire electrically connects the base portion to the second lead.

### BRIEF DESCRIPTION OF DRAWINGS

FIG. 1 is a plan view illustrating a semiconductor device according to a first embodiment.

FIG. 2 is a cross-sectional view taken along line A-A in FIG. 1.

FIG. 3 is a cross-sectional view taken along line B-B of FIG. 1.

FIG. 4 is a cross-sectional view illustrating the semiconductor device mounted on a circuit board according to the first embodiment.

FIG. 5 is a plan view illustrating a semiconductor device according to a first comparative example.

FIG. 6 is a cross-sectional view illustrating the semiconductor device mounted on a circuit board according to a first comparative example.

FIG. 7 is a block diagram illustrating a semiconductor device according to a second embodiment.

FIG. 8 is a plan view illustrating the semiconductor device according to the second embodiment.

FIG. 9 is a cross-sectional view taken along line A-A of FIG. 8.

FIG. 10 is a block diagram illustrating a semiconductor device according to a third embodiment.

FIG. 11 is a plan view of the semiconductor device according to the third embodiment.

FIG. 12 is a perspective view illustrating the semiconductor device according to the third embodiment.

### DETAILED DESCRIPTION OF EMBODIMENTS

A reference potential such as a ground potential is supplied to a base portion of a lead frame via a lead connected to the base portion. When a semiconductor chip mounted on the base portion generates heat, the heat is conducted to an external substrate or the like via the lead. Thereby, a defect may occur in the external substrate or a bonding portion between the external substrate and the semiconductor device.

The present disclosure has been made in view of the above problem, and an object of the present disclosure is to suppress heat conduction from the base portion to the outside via the lead.

### Details of Embodiments of the Present Disclosure

First, the contents of the embodiments of this disclosure are listed and explained.
(1) A semiconductor device according to the present disclosure includes a semiconductor chip, a lead frame, and a bonding wire. The lead frame includes a base portion on which the semiconductor chip is mounted, a first lead separated from the base portion and electrically connected to the semiconductor chip, and a second lead separated from the base portion, and the bonding wire electrically connects the base portion to the second lead. This allows the heat conduction from the base portion to the outside via the leads to be suppressed.
(2) In the above (1), the lead frame may include a third lead connected to the base portion. This allows separation between the base portion and the first and second leads to be suppressed.
(3) In the above (2), a first shortest distance between a first position where the semiconductor chip is mounted on the base portion and a second position where the third lead is connected to the base portion may be longer than a second shortest distance between the first position and a third position where the bonding wire is bonded to the base portion. This can suppress the heat conduction to the third lead.
(4) In the above (2), the semiconductor device further may include a passive chip including a passive element and not including an active element, a part of the passive chip being mounted on a part of a region between a first position where the semiconductor chip is mounted on the base portion and a second position where the third lead is connected to the base portion. The semiconductor chip may include an active element. The passive chip may not be mounted between the first location and a third location where the bonding wire is bonded to the base portion. This can suppress the heat conduction to the third lead.
(5) In the above (2), the semiconductor device further may include a passive chip mounted on the base portion. The semiconductor chip may include a transistor. The passive chip may include at least a part of a matching circuit matching impedances of the transistor and an input terminal or an output terminal with each other. The input terminal or the output terminal is the first lead. The first lead may be electrically connected to the transistor via the matching circuit. At least a part of the passive chip may be mounted on at least a part of a region between a first position where the semiconductor chip is mounted on the base portion and a second position where the third lead is connected to the base portion, and may not be mounted between the first position and a third position where the bonding wire is bonded to the base portion. This can suppress the heat conduction to the third lead.
(6) In the above (5), the semiconductor device further may include a sealer that seals the lead frame and the semiconductor chip. The first lead may include an input lead to which a high frequency signal is input and an output lead from which a high frequency signal is output. The input lead and the output lead may be provided on a pair of opposing first sides of the sealer, respectively. The third lead may be provided on at least one of the pair of opposing first sides and may not be provided on another pair of opposing second sides of the sealer. The second lead may be provided on at least one of the another pair of opposing second sides. This can suppress the heat conduction to the third lead.
(7) In any one of the above (1) to (4), the semiconductor device further may include a passive chip mounted on the base portion. The semiconductor chip may include a transistor. The passive chip may include at least a part of a matching circuit matching impedances of the transistor and an input terminal or an output terminal with each other. The input terminal or the output terminal is the first lead. The first lead may be electrically connected to the transistor via the matching circuit. This allows the conduction of heat generated in the transistor to the outside via the leads to be suppressed.
(8) In any one of the above (1) to (5), the semiconductor device further may include a sealer that seals the lead frame and the semiconductor chip and has a first surface and a second surface opposite to each other. An end of the first lead and an end of the second lead may be exposed from the first surface of the sealer. A first surface of the base portion opposite to a second surface of the base portion on which the semiconductor chip is mounted may be exposed from the second surface of the sealer. Thereby, electrical connection to the semiconductor chip can be performed from the first surface of the sealer, and heat dissipation of the semiconductor chip can be performed from the second surface of the sealer.
(9) In the above (8), an end of the first lead exposed from the first surface of the sealer and an end of the second lead exposed from the first surface of the sealer may be bonded to a circuit board using a bonding member. This can suppress deterioration of the bonding member.
(10) In the above (9), the first surface of the base portion exposed from the second surface of the sealer may be bonded to a heat dissipation member. This allows heat generated in the semiconductor chip to be mainly dissipated from the heat dissipation member.

Specific examples of a semiconductor device according to embodiments of the present disclosure will be described below with reference to the drawings. It should be noted that the present disclosure is not limited to these examples, but is defined by the claims and is intended to include all modifications within the meaning and scope equivalent to the claims.

### First Embodiment

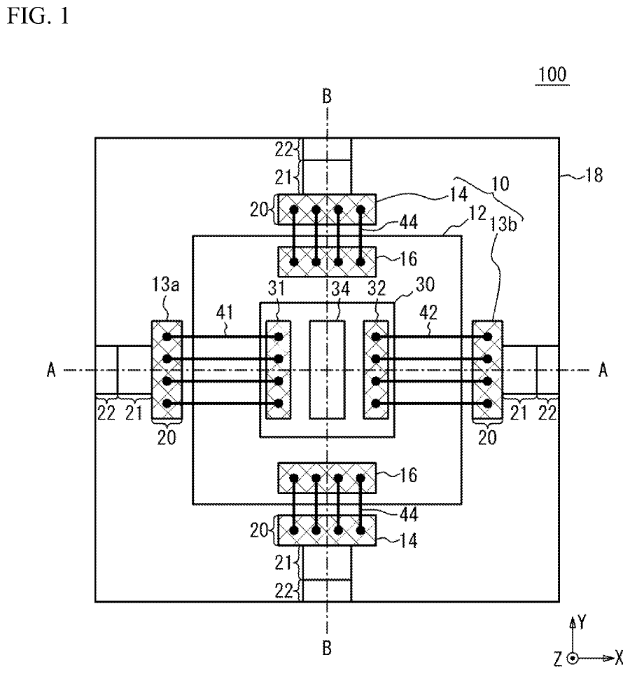

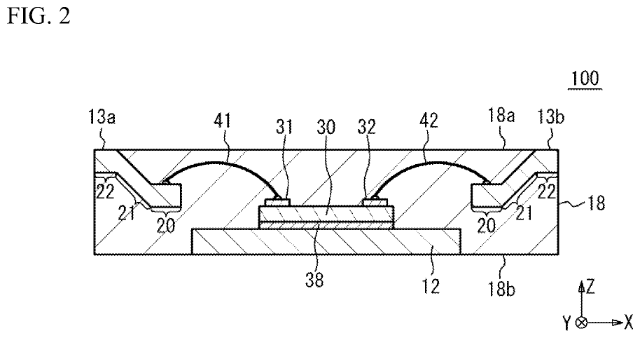

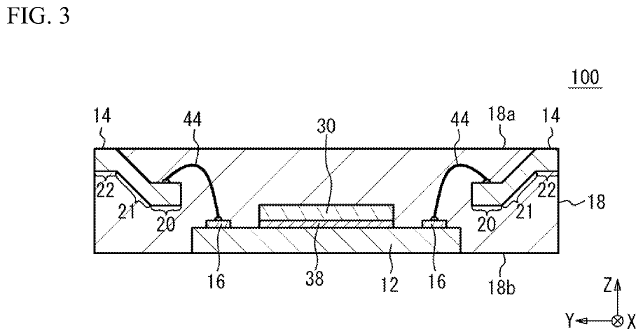

FIG. 1 is a plan view illustrating a semiconductor device according to a first embodiment. FIG. 2 is a cross-sectional view taken along line A-A in FIG. 1. FIG. 3 is a cross-sectional view taken along line B-B of FIG. 1. In FIG. 1, a sealer 18 is illustrated transparently. A thickness direction of the sealer 18 is defined as a Z direction, and extending directions of sides in a planar shape of the sealer 18 are defined as an X direction and a Y direction.

As illustrated in FIGS. 1 to 3, in a semiconductor device 100 of the first embodiment, a lead frame 10 includes a base portion 12 and leads 13a, 13b and 14. The leads 13a, 13b and 14 are separated from the base portion 12. The leads 13a and 13b are provided so as to dispose the base portion 12 therebetween in the X direction, and the leads 14 are provided so as to dispose the base portion 12 therebetween in the Y direction.

A semiconductor chip 30 is mounted on an upper surface of the base portion 12 via a bonding material 38. Pads 16 to which bonding wires 44 are connected are provided on the base portion 12. Each of the leads 13a, 13b, and 14 has a pad portion 20 to which the bonding wires 41, 42, or 44 are bonded, an end 22 exposed from the sealer 18, and a connecting portion 21 connecting the pad portion 20 and the end 22.

The semiconductor chip 30 has an input pad 31 and an output pad 32 on its upper surface. The pad portion 20 of the lead 13a and the input pad 31 are electrically connected and short-circuited by bonding wires 41. The pad portion 20 of the lead 13b and the output pad 32 are electrically connected and short-circuited by bonding wires 42. The pad portions 20 of the leads 14 and the pads 16 are electrically connected and short-circuited by bonding wires 44.

The lead frame 10 and the semiconductor chip 30 are sealed by the sealer 18. The ends 22 of the leads 13a, 13b, and 14 are exposed from a first surface 18a of the sealer 18, and a lower surface of the base portion 12 is exposed from a second surface 18b of the sealer 18. The semiconductor chip 30 includes, for example, a transistor 34. The transistor 34 is, for example, a field effect transistor (FET). In the cross-sectional view, the transistor 34 is not illustrated.

The lead frame 10 is a metal plate containing copper as a main component, for example. The semiconductor chip 30 is, for example, a GaN-based semiconductor chip, a silicon-based semiconductor chip, or a GaAs-based semiconductor chip, and includes a GaN HEMT (Gallium Nitride High Electron Mobility Transistor) as an example. A metal film containing, for example, gold as a main component is formed on the upper surfaces of the pads 16 and the pad portions 20. The metal film is a film for improving adhesion with the bonding wires 41, 42, and 44. The metal film may not be provided. The bonding wires 41, 42 and 44 are, for example, gold wires or aluminum wires. The bonding material 38 is conductive, and is, for example, a brazing material such as solder or a metal paste such as silver paste. The sealer 18 is, for example, an organic insulator containing resin such as epoxy resin as a main component.

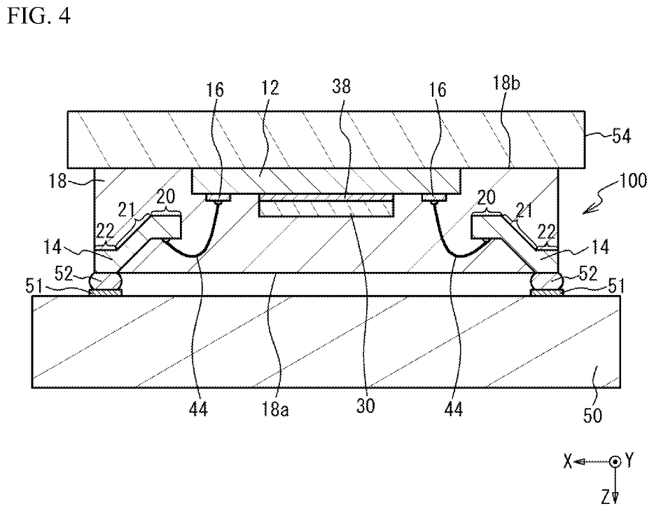

FIG. 4 is a cross-sectional view illustrating the semiconductor device mounted on a circuit board according to the first embodiment. FIG. 4 corresponds to the B-B cross section of FIG. 1. In FIG. 4, the top and bottom of the semiconductor device 100 are reversed from those in FIG. 3. Lands 51 are provided on a circuit board 50. The ends 22 of the leads 14 exposed from the first surface 18a are bonded to the lands 51 by bonding members 52 such as a solder. The base portion 12 exposed from the second surface 18b is bonded to a heat dissipation member 54 such as a heat sink.

The circuit board 50 is, for example, a printed circuit board (PCB). The land 51 is a metal layer such as a copper layer or a gold layer, for example. The heat dissipation member 54 is made of a material having a high thermal conductivity such as copper.

A signal (for example, a high frequency signal) that passes from the circuit board 50 through the land 51 and the bonding member 52 and is input to the end 22 of the lead 13a passes through the lead 13a, the bonding wires 41, and the input pad 31 and is input to the transistor 34. A signal (for example, a high frequency signal) outputted from the transistor 34 passes through the pad 32, the bonding wires 42, the lead 13b, the end 22 of the lead 13b, the bonding member 52, and the land 51, and is outputted to the circuit board 50. A reference potential such as a ground potential is supplied to a ground pad (for example, the lower surface of the semiconductor chip 30) of the transistor 34 via the lead 14, the bonding wires 44, the pad 16, the base portion 12, and the bonding material 38. Heat emitted from the semiconductor chip 30 is conducted to the heat dissipation member 54 via the bonding material 38 and the base portion 12.

### First Comparative Example

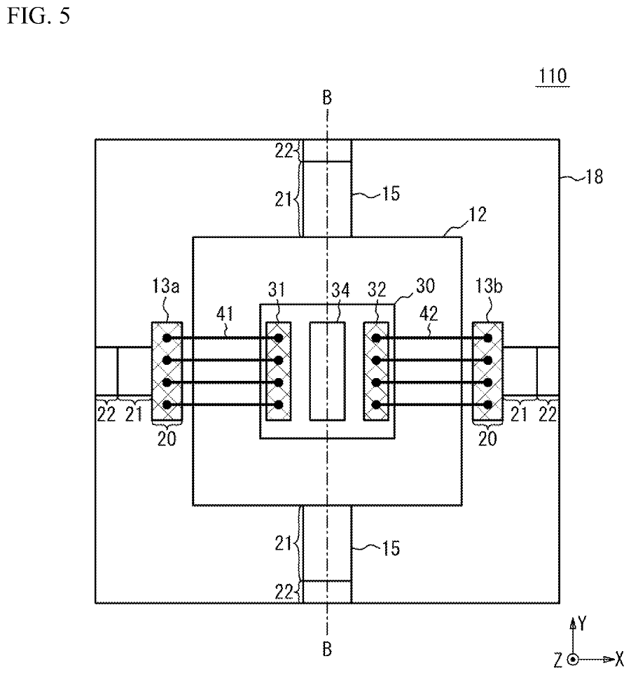

FIG. 5 is a plan view illustrating a semiconductor device according to a first comparative example. In FIG. 5, the sealer 18 is illustrated transparently. As illustrated in FIG. 5, in a semiconductor device 110 of the first comparative example, leads 15 are provided instead of the leads 14. The leads 15 are provided so as to sandwich the base portion 12 in the Y direction and are connected to the base portion 12. The pads 16 and the bonding wires 44 are not provided. A reference potential is supplied to the base portion 12 via the lead 15. Other configurations are the same as those of the first embodiment.

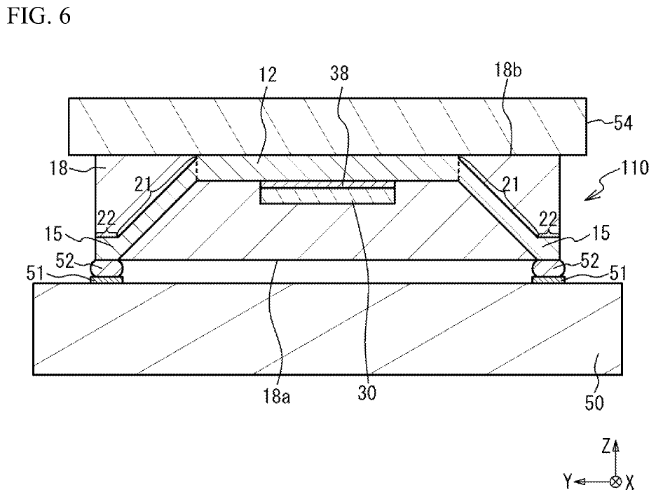

FIG. 6 is a cross-sectional view illustrating the semiconductor device mounted on the circuit board according to the first comparative example. FIG. 6 corresponds to the B-B cross section of FIG. 5. As illustrated in FIG. 6, in the first comparative example, a reference potential such as a ground potential is supplied to the source via the lead 15, the base portion 12, and the bonding material 38. Thus, the reference potential can be supplied to the base portion 12 in the first comparative example as in the first embodiment. However, heat emitted from the semiconductor chip 30 is conducted to the bonding member 52 via the lead 15. Therefore, the temperature of the bonding member 52 increases. Thereby, the bonding member 52 may deteriorate. Further, when the heat is transferred to the circuit board 50, the temperature of the circuit board 50 may increase. Thereby, the circuit board 50 or an electronic component mounted on the circuit board 50 may deteriorate.

### Description of First Embodiment

On the other hand, in the first embodiment, the leads 13a and 13b (first lead) are separated from the base portion 12 and electrically connected to the semiconductor chip 30. The leads 14 (second lead) are separated from the base portion 12 on which the semiconductor chip 30 is mounted. Therefore, heat generated in the semiconductor chip 30 can be suppressed from being conducted to the leads 14. The bonding wires 44 electrically connects the base portion 12 to the leads 14. Thus, the reference potential can be supplied to the base portion 12. A thermal resistance of the bonding wires 44 is higher than that of the leads 14. Therefore, the reference potential can be supplied to the base portion 12, and heat conduction to the lead 14 can be suppressed. Therefore, it is possible to suppress deterioration of the bonding member 52, deterioration of the circuit board 50, and the like.

The sealer 18 seals the lead frame 10 and the semiconductor chip 30. The sealer 18 has the first surface 18a and the second surface 18b opposed to each other. The ends 22 of the leads 13a, 13b, and 14 are exposed from the first surface 18a of the sealer 18. A surface of the base portion 12 opposite to the surface of the base portion 12 on which the semiconductor chip 30 is mounted is exposed from the second surface 18b. Thus, electrical connection to the semiconductor chip 30 can be made from the first surface 18a, and heat dissipation from the semiconductor chip 30 can be made from the second surface 18b opposite to the first surface 18a.

The ends 22 of the leads 13a, 13b, and 14 exposed from the first surface 18a are bonded to the circuit board 50 using the bonding member 52. Thus, the reference potential can be supplied from the circuit board 50 to the base portion 12. In addition, signals can be supplied from the circuit board 50 to the semiconductor chip 30. Further, since heat conduction from the base portion 12 to the bonding member 52 can be suppressed, deterioration of the bonding member 52 can be suppressed.

The surface of the base portion 12 exposed from the second surface 18b is bonded to the heat dissipation member 54. By bonding the heat dissipation member 54 to the base portion 12, the thermal resistance from the base portion 12 to the heat dissipation member 54 can be made lower than the thermal resistance of the bonding wires 44. Therefore, the heat generated in the semiconductor chip 30 can be dissipated mainly from the heat dissipation member 54.

### Second Embodiment

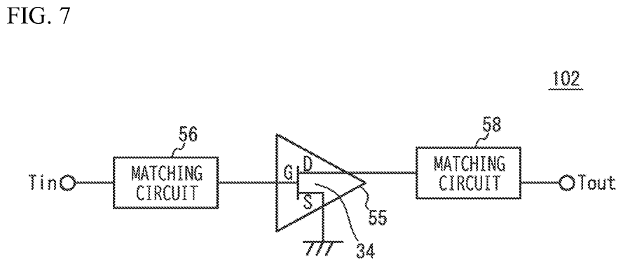

A second embodiment represents an example of an amplifier circuit. FIG. 7 is a block diagram illustrating a semiconductor device according to a second embodiment. As illustrated in FIG. 7, a semiconductor device 102 includes an amplifier 55 and matching circuits 56 and 58. The amplifier 55 includes the transistor 34. The transistor 34 is, for example, an FET, and includes a source S, a gate G, and a drain D. The source S is grounded. A high frequency signal input from an input terminal Tin passes through the matching circuit 56 and is input to the gate G. The high frequency signal amplified by the transistor 34 is output from the drain D to an output terminal Tout through the matching circuit 58. The matching circuit 56 matches an impedance viewed from the input terminal Tin to the matching circuit 56 with an impedance viewed from the matching circuit 56 to the gate G. The matching circuit 58 matches an impedance viewed from the drain D to the matching circuit 58 with an impedance viewed from the matching circuit 58 to the output terminal Tout. The high frequency signal is, for example, a microwave (300 MHz to 30 GHz) or a millimeter wave (30 GHz to 300 GHz).

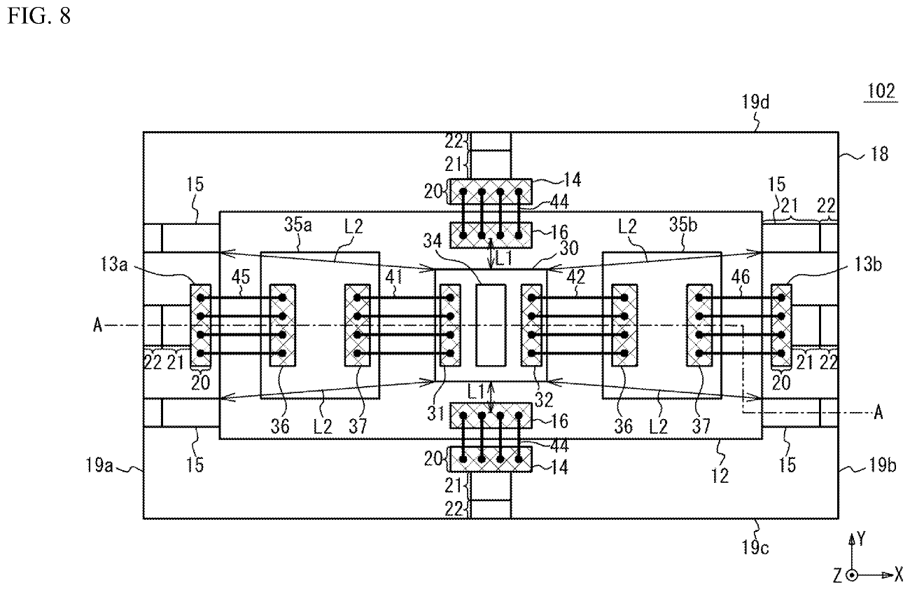

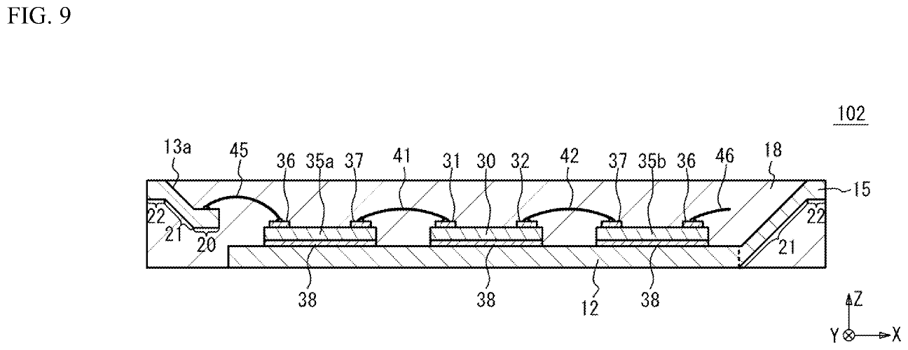

FIG. 8 is a plan view illustrating the semiconductor device according to the second embodiment. FIG. 9 is a cross-sectional view taken along line A-A in FIG. 8. As illustrated in FIGS. 8 and 9, in the semiconductor element 102 according to the second embodiment, the lead frame 10 includes the base portion 12 and the leads 13a, 13b, 14 and 15. The leads 15 are connected to the base portion 12. The leads 13a and 13b are provided so as to dispose the base portion 12 therebetween in the X direction, and the leads 15 are provided so as to dispose the base portion 12 therebetween in the X direction. The leads 14 are provided so as to dispose the base portion 12 therebetween in the Y direction.

The semiconductor chip 30 and passive chips 35a and 35b are mounted on the upper surface of the base portion 12 via the bonding material 38. The pads 16 to which the bonding wires 44 are connected are provided on the base portion 12. Each of the passive chips 35a and 35b has an input pad 36 and an output pad 37 on its upper surface. The pad portion 20 of the lead 13a and the input pad 36 of the passive chip 35a are electrically connected and short-circuited by bonding wires 45. The output pad 37 of the passive chip 35a and the input pad 31 of the semiconductor chip 30 are electrically connected and short-circuited by the bonding wires 41. The output pad 32 of the semiconductor chip 30 and the input pad 36 of the passive chip 35b are electrically connected and short-circuited by the bonding wires 42. The output pad 37 of the passive chip 35b and the pad portion 20 of the lead 13b are electrically connected and short-circuited by bonding wires 46. The pad portions 20 of the leads 14 and the pads 16 are electrically connected and short-circuited by bonding wires 44.

The leads 13a and 13b correspond to the input terminal Tin and the output terminal Tout of FIG. 7, respectively. The semiconductor chip 30 corresponds to the amplifier 55 of FIG. 7. The passive chip 35a and the bonding wires 45 and 41 correspond to the matching circuit 56 of FIG. 7. The passive chip 35b and the bonding wires 42 and 46 correspond to the matching circuit 58 of FIG. 7.

In the first embodiment, the leads 15 connected to the base portion 12 are not provided. In this case, the base portion 12 and leads 13a, 13b, and 14 may be separated from each other when the semiconductor device 100 is assembled. Therefore, in the second embodiment, the lead frame 10 includes the leads 15 (third lead) connected to the base portion 12. This can suppress the separation between the base portion 12 and the leads 13a, 13b and 14.

In the case of providing the leads 15, if the leads 15 are closer to the semiconductor chip 30 than the pads 16, heat generated in the semiconductor chip 30 is conducted to the leads 15. On the other hand, the reference potential cannot be supplied to the vicinity of the semiconductor chip 30 unless the leads 14, the bonding wires 44 and the pads 16 are provided. As a result, a ground level of the semiconductor chip 30 becomes unstable. Therefore, a distance L2 is made longer than a distance L1. Here, the distance L2 is a shortest distance between a first position where the semiconductor chip 30 is mounted on the base portion 12 and a second position where each of the leads 15 is connected to the base portion 12. The distance L1 is a shortest distance between the first position where the semiconductor chip 30 is mounted on the base portion 12 and a third position where the bonding wires 44 are bonded to the base portion 12. Thus, since the leads 15 are far from the semiconductor chip 30, the heat generated in the semiconductor chip 30 can be suppressed from being conducted to the leads 15. By providing the pads 16 near the semiconductor chip 30, the ground level of the semiconductor chip 30 can be stabilized.

In view of the above, the distance L2 may be 1.5 times or more, 2 times or more, or 3 times or more the distance L1. The distance L2 is, for example, 100 times or less the distance L1.

The semiconductor chip 30 includes active elements such as the transistor 34 and a diode. The passive chips 35a and 35b include passive elements such as capacitors, inductors, and resistors, but do not include active elements. For this reason, the semiconductor chip 30 generates heat, but the passive chips 35a and 35b hardly generate heat. Therefore, the passive chips 35a and 35b are mounted between the first position where the semiconductor chip 30 is mounted on the base portion 12 and the second position where each of the leads 15 is connected to the base portion 12. The passive chip is not mounted between the first position where the semiconductor chip 30 is mounted on the base portion 12 and the third position where the bonding wires 44 are bonded to the base portion 12. Since the passive chips 35a and 35b are mounted between the semiconductor chip 30 and the leads 15, heat generated in the semiconductor chip 30 can be suppressed from being conducted to the leads 15. Since the passive chips 35a and 35b are not mounted between the semiconductor chip 30 and the pads 16, the ground level of the semiconductor chip 30 can be stabilized.

At least a part of the passive chip 35a (or 35b) may be provided on at least a part of a region between the first position and the second position. That is, the passive chip 35a (or 35b) may interrupt at least one straight line from the first position where the semiconductor chip 30 is mounted on the base portion 12 to the second position where each of the leads 15 is connected to the base portion 12. In FIG. 8, all of the straight lines from the first position where the semiconductor chip 30 is mounted on the base portion 12 to the second position where each of the leads 15 is connected to the base portion 12 are interrupted by the passive chip 35a (or 35b). This allows the heat generated in the semiconductor chip 30 to be more suppressed from being conducted to the leads 15.

The passive chip 35a includes at least a part of the matching circuit 56 that matches impedances of the transistor 34 and the input terminal Tin with each other, and the passive chip 35b includes at least a part of the matching circuit 58 that matches impedances of the transistor 34 and the output terminal Tout with each other. In such a configuration, the transistor 34 generates heat. Therefore, the leads 14 and the bonding wires 44 can be provided. When the transistor 34 is a transistor for a power amplifier, the semiconductor chip 30 in particular generates heat. Therefore, the leads 14 and the bonding wires 44 can be provided. Note that at least one of the matching circuits 56 and 58 may be provided.

The matching circuits 56 and 58 hardly generate heat. Therefore, the passive chips 35a and 35b can be mounted between the semiconductor chip 30 and the leads 15, respectively, and the passive chips 35a and 35b cannot be mounted between the semiconductor chip 30 and the pads 16, respectively.

The lead 13a is an input lead to which the high frequency signal is input, and the lead 13b is an output lead from which the high frequency signal is output. In this case, the leads 13a and 13b are provided on a pair of opposing sides 19a and 19b (first side) of the sealer 18, respectively. This is to suppress interference between the input signal and the output signal. The leads 15 are provided on the sides 19a and 19b and are not provided on another pair of opposing sides 19c and 19d (second sides) of the sealer 18. The leads 14 are provided on the sides 19c and 19d. This arrangement allows the passive chips 35a and 35b to be mounted between the semiconductor chip 30 and the leads 15, and allows the passive chips 35a and 35b not to be mounted between the semiconductor chip 30 and the pads 16. Therefore, heat generated in the semiconductor chip 30 can be suppressed from being conducted to the lead 15, and the ground level of the semiconductor chip 30 can be stabilized.

The lead 15 may be provided on at least one of the sides 19a and 19b, and the lead 14 may be provided on at least one of the sides 19c and 19d.

### Third Embodiment

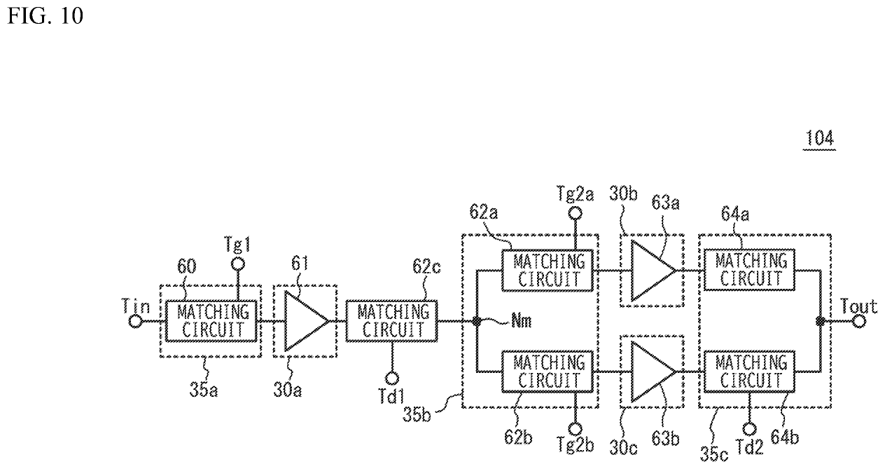

A third embodiment is an example of an amplifying device including a Doherty amplifier used in a base station of mobile communication. FIG. 10 is a block diagram illustrating a semiconductor device according to the third embodiment. As illustrated in FIG. 10, in a semiconductor device 104, the semiconductor device 104 includes amplifiers 61, 63a and 63b, and matching circuits 60, 62a, 62b, 62c, 64a and 64b. The semiconductor device 104 is a two-stage amplifying device. The high frequency signal inputted from the input terminal Tin is amplified by the amplifier 61, further amplified by the amplifiers 63a and 63b, and outputted from the output terminal Tout. The matching circuit 60 is mounted on the passive chip 35a, the matching circuits 62a and 62b are mounted on the passive chip 35b, and the matching circuits 64a and 64b are mounted on a passive chip 35c. The amplifiers 61, 63a and 63b are, for example, transistors such as FETs, and are mounted on the semiconductor chips 30a to 30c, respectively. The amplifier 61 is a driver amplifier. The amplifiers 63a and 63b are power amplifiers and are Doherty amplifiers.

The input terminal Tin is connected to the amplifier 61 via the matching circuit 60. The matching circuit 60 matches an impedance viewed from the input terminal Tin to the matching circuit 60 with an impedance viewed from the matching circuit 60 to the amplifier 61. The matching circuit 60 supplies a gate bias from a bias terminal Tg1 to the amplifier 61. The output of the amplifier 61 is connected to a node Nm via the matching circuit 62c. The matching circuit 62c matches an impedance viewed from the amplifier 61 to the matching circuit 62c with an impedance viewed from the matching circuit 62c to the node Nm. The matching circuit 62c supplies a drain bias from a bias terminal Td1 to the amplifier 61. The output of the amplifier 61 is branched at the node Nm and the branched outputs are connected to the amplifiers 63a and 63b via the matching circuits 62a and 62b, respectively.

The matching circuit 62a matches an impedance viewed from the node Nm to the matching circuit 62a with an impedance viewed from the matching circuit 62a to the amplifier 63a. The matching circuit 62a supplies the gate bias from a bias terminals Tg2a to the amplifier 63a. The matching circuit 62b matches an impedance viewed from the node Nm to the matching circuit 62b with an impedance viewed from the matching circuit 62b to the amplifier 63b. The matching circuit 62b supplies the gate bias from a bias terminals Tg2b to the amplifier 63b. The outputs of the amplifiers 63a and 63b are combined via matching circuits 64a and 64b, respectively, and connected to the output terminal Tout. The matching circuit 64a matches an impedance viewed from the amplifier 63a to the matching circuit 64a with an impedance viewed from the matching circuit 64a to the output terminal Tout. The matching circuit 64b matches an impedance viewed from the amplifier 63b to the matching circuit 64b with an impedance viewed from the matching circuit 64b to the output terminal Tout. The matching circuit 64b supplies a drain bias from a bias terminal Td2 to the amplifiers 63a and 63b.

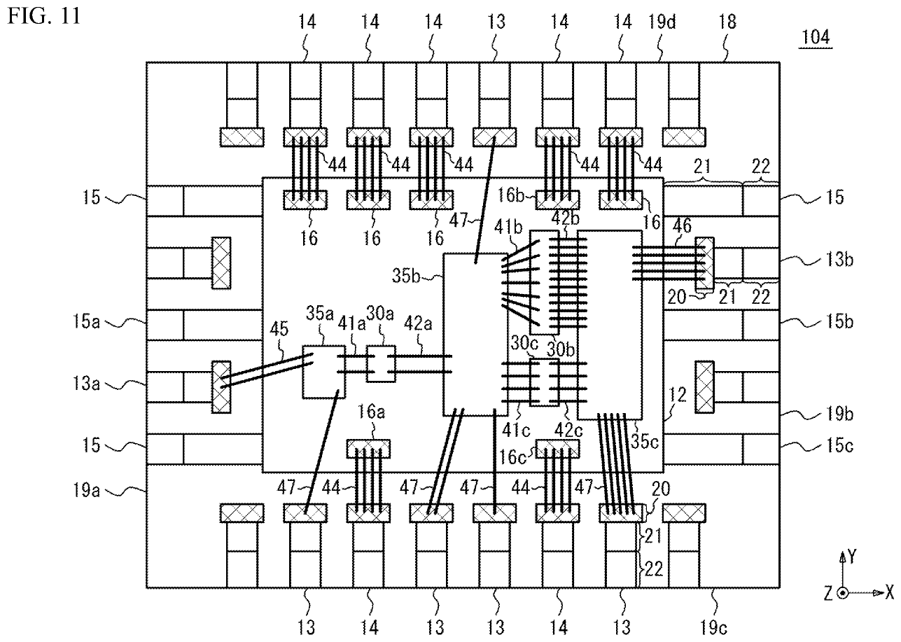

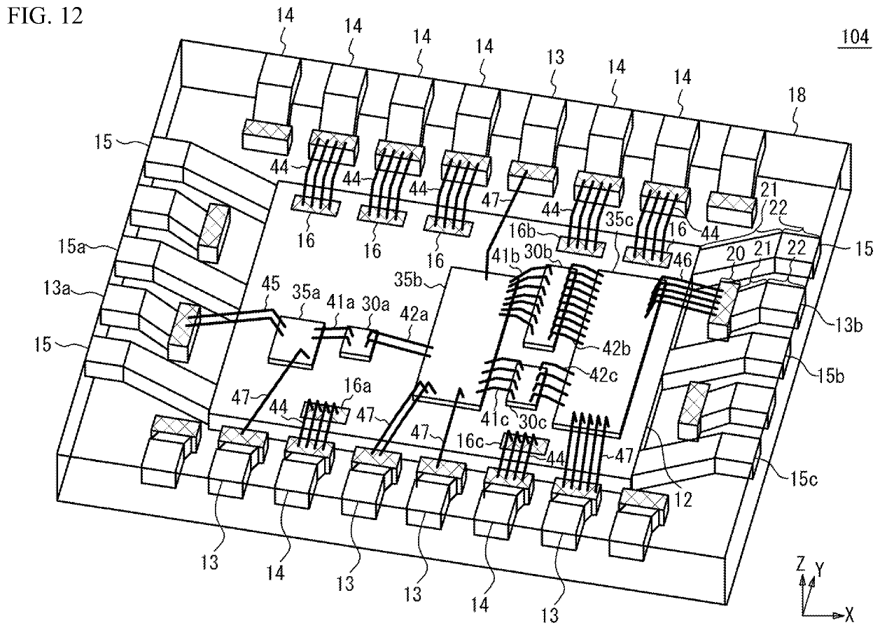

FIG. 11 is a plan view illustrating a semiconductor device according to a third embodiment. FIG. 12 is a perspective view illustrating the semiconductor device according to the third embodiment. In FIG. 11, the sealer 18 is illustrated transparently. As illustrated in FIGS. 11 and 12, in the semiconductor device 104, semiconductor chips 30a to 30c and passive chips 35a to 35c are mounted on the base portion 12. The leads 13a and 15 are provided on the side 19a of the sealer 18, the leads 13b and 15 are provided on the side 19b. The leads 13 and 14 are provided on each of the sides 19c and 19d.

The bonding wires 45 electrically connect the lead 13a to the passive chip 35a, bonding wires 41a electrically connect the passive chip 35a to the semiconductor chip 30a, and bonding wires 42a electrically connect the semiconductor chip 30a to the passive chip 35b. Bonding wires 41b electrically connect the passive chip 35b to the semiconductor chip 30b, and bonding wires 41c electrically connect the passive chip 35b to the semiconductor chip 30c. Bonding wires 42b electrically connect the semiconductor chip 30b to the passive chip 35c, bonding wires 42c electrically connect the semiconductor chip 30c to the passive chip 35c, and the bonding wires 46 electrically connect the passive chip 35c to the lead 13b. Bonding wires 47 electrically connect the leads 13 to the passive chips 35a to 35c. The bonding wires 44 electrically connect the leads 14 to pads 16, 16a, 16b and 16c.

The lead 13a corresponds to the input terminal Tin of FIG. 9, and the lead 13b corresponds to the output terminal Tout of FIG. 9. The leads 13 correspond to the bias terminals Tg1, Td1, Tg2a, Tg2b, and Td2 in FIG. 9.

The leads 15 closest to the semiconductor chips 30a, 30b, and 30c are the leads 15a, 15b, and 15c, respectively. The pads 16 closest to the semiconductor chips 30a, 30b, and 30c are the pads 16a, 16b, and 16c, respectively. Positions where the leads 15a to 15c are connected to the base portion 12 should be farther from the semiconductor chips 30a to 30c than the pads 16a to 16c. This suppresses heat generated in the semiconductor chips 30a to 30c from being conducted to the leads 15a to 15c, respectively. The ground level of the semiconductor chips 30a to 30c can be stabilized.

In addition, at least parts of the passive chips 35a to 35c may be provided on at least parts of regions between positions where the leads 15a to 15c are connected to the base portion 12 and the semiconductor chip 30a to 30c, respectively. This suppresses heat generated in the semiconductor chips 30a to 30c from being conducted to the leads 15a to 15c, respectively. Also, the passive chips 35a to 35c should not be provided between the pads 16a to 16c and the semiconductor chips 30a to 30c, respectively. This allows the ground level of the semiconductor chips 30a to 30c to be stable. Although a two-stage amplifying device has been described as an example of the amplifying device, a single-stage amplifying device or an amplifying device having three or more stages may be used.

The embodiments disclosed here should be considered illustrative in all respects and not restrictive. The present disclosure is not limited to the specific embodiments described above, but various variations and changes are possible within the scope of the gist of the present disclosure as described in the claims.

What is claimed is:

1. A semiconductor device comprising:
a semiconductor chip;
a lead frame; and
a bonding wire;
wherein the lead frame includes a base portion on which the semiconductor chip is mounted, a first lead separated from the base portion and electrically connected to the semiconductor chip, and a second lead separated from the base portion, and
the bonding wire electrically connects the base portion to the second lead.

2. The semiconductor device according to claim 1, wherein
the lead frame includes a third lead connected to the base portion.

3. The semiconductor device according to claim 2, wherein
a first shortest distance between a first position where the semiconductor chip is mounted on the base portion and a second position where the third lead is connected to the base portion is longer than a second shortest distance between the first position and a third position where the bonding wire is bonded to the base portion.

4. The semiconductor device according to claim 2, further comprising:
a passive chip including a passive element and not including an active element, a part of the passive chip being mounted on a part of a region between a first position where the semiconductor chip is mounted on the base portion and a second position where the third lead is connected to the base portion;
wherein the semiconductor chip includes an active element, and
the passive chip is not mounted between the first location and a third location where the bonding wire is bonded to the base portion.

5. The semiconductor device according to claim 2, further comprising:
a passive chip mounted on the base portion;
wherein the semiconductor chip includes a transistor,
the passive chip includes at least a part of a matching circuit matching impedances of the transistor and an input terminal or an output terminal with each other, the input terminal or the output terminal being the first lead,
the first lead is electrically connected to the transistor via the matching circuit, and
at least a part of the passive chip is mounted on at least a part of a region between a first position where the semiconductor chip is mounted on the base portion and a second position where the third lead is connected to the base portion, and is not mounted between the first position and a third position where the bonding wire is bonded to the base portion.

6. The semiconductor device according to claim 5, further comprising:
a sealer that seals the lead frame and the semiconductor chip;
wherein the first lead includes an input lead to which a high frequency signal is input and an output lead from which a high frequency signal is output,
the input lead and the output lead are provided on a pair of opposing first sides of the sealer, respectively,
the third lead is provided on at least one of the pair of opposing first sides and is not provided on another pair of opposing second sides of the sealer, and
the second lead is provided on at least one of the another pair of opposing second sides.

7. The semiconductor device according to claim 1, further comprising:
a passive chip mounted on the base portion;
wherein the semiconductor chip includes a transistor,
the passive chip includes at least a part of a matching circuit matching impedances of the transistor and an input terminal or an output terminal with each other, the input terminal or the output terminal being the first lead, and
the first lead is electrically connected to the transistor via the matching circuit.

8. The semiconductor device according to claim 1, further comprising:
a sealer that seals the lead frame and the semiconductor chip and has a first surface and a second surface opposite to each other;
wherein an end of the first lead and an end of the second lead are exposed from the first surface of the sealer, and
a first surface of the base portion opposite to a second surface of the base portion on which the semiconductor chip is mounted is exposed from the second surface of the sealer.

9. The semiconductor device according to claim 8, wherein
an end of the first lead exposed from the first surface of the sealer and an end of the second lead exposed from the first surface of the sealer are bonded to a circuit board using a bonding member.

10. The semiconductor device according to claim 9, wherein
the first surface of the base portion exposed from the second surface of the sealer is bonded to a heat dissipation member.
